(19) United States
(12) Patent Application Publication
(10) Pub. No.: US 2026/0096096 A1
(43) Pub. Date: Apr. 2, 2026

(54) Uniform e-Field Multi-site-cell Formation

(71) Applicant: SK hynix Inc., Gyeonggi-do (KR)

(72) Inventors: Tong ZHANG, San Jose, CA (US); Jungdal CHOI, San Jose, CA (US); Sung-Taeg KANG, San Jose, CA (US); Sungwon LIM, San Jose, CA (US); Agus TJANDRA, San Jose, CA (US)

(21) Appl. No.: 18/899,682

(22) Filed: Sep. 27, 2024

(51) Int. Cl. H10B 43/27; H10B 43/10

(52) U.S. Cl. CPC H10B 43/27; H10B 43/10

(57) ABSTRACT

A method of making a multi-slit structure comprising a uniform e-field multi-site-cell formation having less curvature for cell width. The method employs an oval shape channel hole and reverse sacrificial layer deposition or area-selective deposition. The multi-slit cell areas are formed on the wide sides of the channel hole and are separated at the corner areas of the channel hole.

### FIELD OF THE INVENTION

The present invention generally relates to 3-dimensional (“3-D”) semiconductor technology and, more particularly, to multi-site cell (MSC) semiconductor technology.

### BACKGROUND

For increased cell integration (or density) in 3D NAND semiconductor devices, advanced memory sell designs storing multiple bits per cell such as 2 (Multi-Level Cells or MLC), 3 (Triple-Level Cells or TLC), 4 (Quad Level Cells or QLC) and even 5 (Penta Level Cells or PLC) compared to Single Logic Cell (SLC) have been developed. Also, various vertical (100, 200, 300, 400 stacks), lateral (4, 9, 14, 19, 24 rows), and structural (4D, PUA, HWB) scaling methods have been proposed. However, these efforts for increasing integration are reaching their limits in terms of physical limitations and high cost. Hence, additional physical scaling methods are needed. One recently proposed method includes formation of multi-site cells, also often referred to as multi-slit cells. Examples of MSC method patents include U.S. Pat. No. 11,716,847 B2 to Gao et al. and U.S. Pat. No. 11,545,190 B2.

### SUMMARY OF THE INVENTION

The present invention disclosure provides a new method of making an MSC structure comprising a uniform e-field multi-site-cell (uf-MSC) formation having less curvature for cell width. The method employs reverse sacrificial layer deposition or area-selective deposition. The method may provide uniform carrier injection for a 3D NAND device.

The present inventive method provides a continuous MSC (Multi-Site-Cell) structure that can secure sufficient cell separation and storage node area by employing a reverse non-conformal sacrificial layer to separate (split) the main cell in a plurality of cells. The inventive method provides a significant improvement both regarding the structural integrity of the MSCs and their performance characteristics over methods which result in multiple cells with large curvature.

The present inventive method drastically improves the cell characteristics compared because the MSCs have less curvature and also have a continuous and sufficient storage node area. The method includes cutting the cell layers by using a reverse non-conformal sacrificial layer after the deposition of a channel poly-Si and liner oxide layers. Such uniform field multi-site-cells (uf-MSC) is formed by using less curvature for cell width split from elliptical main cell.

According to an embodiment of the present invention a method for making MSCs may include providing a stack of alternating thin films of oxides and nitrides, also referred to hereinafter as an ONON stack. Then an oval shape channel hole is formed extending through the stack. Then, a first oxide layer, a nitride layer, and a second oxide layer are formed sequentially over a sidewall of the channel hole. The method further includes forming a channel poly-Si layer on the second oxide layer, and covering the channel poly-Si layer with a liner oxide layer. The method further includes forming a reverse non-conformal sacrificial layer on the liner oxide layer. The reverse non conformal sacrificial layer is formed so that a thickness of the reverse non-conformal sacrificial layer at a center of a wide side of the oval shape channel hole is thicker than a thickness of the reverse non-conformal sacrificial layer at a center of a narrow side of the oval shape channel hole.

The oval shape channel hole may have two wide sides opposite to each other and two narrow sides opposite to each other, wherein the wide sides are wider and less curved than the narrow sides.

The reverse non-conformal sacrificial layer may include single or multi-layers of SiO₂, Si₃N₄, Poly-Si, metal, and metal silicide.

The reverse non-conformal sacrificial layer may be separated at the center of the narrow sides of the oval shape channel holes to form open areas exposing the liner oxide layer.

The reverse non-conformal sacrificial layer may be separated by a dry or wet separation process.

The method further includes separating the exposed liner oxide layer to expose a portion of the channel poly-Si, then separating the exposed portion of the poly-Si layer to expose in turn a portion of the second oxide layer, then separating the exposed portion of the second oxide layer to expose in turn a portion of the nitride layer, then separating the exposed portion of the nitride layer to expose in turn a portion of the first oxide layer to form a pair of continuous multi-slit cells.

The separating of the exposed portions of the thin liner oxide layer, the channel poly-Si, the second oxide layer, and the nitride layer of the opened areas may include a dry or wet etching operation to form continuous multi-slit cells.

The method forms multi-slit cells at the opposite wide sides of the oval shape channel hole. The formed multi-slit cells are covered by the sacrificial layer.

The method may further include removing any remaining sacrificial layer and gap-filling an open space of the channel hole with an oxide to complete forming of the multi-slit cells.

According to another embodiment of the present invention, a method for making multi-slit cells comprises providing a stack of alternating thin films of oxides and nitrides, forming an oval shape channel hole having a pair of opposite narrower corner sides alternating with a pair of opposite wider, less curved sides. The oval shape channel hole is extending through the stack. The method further comprises forming a first oxide layer, a nitride layer, and a second oxide layer sequentially over a sidewall of the channel hole, forming a channel poly-Si layer on the second oxide layer, and covering the channel poly-Si layer with a liner oxide layer. The method further comprises depositing a first non-conformal sacrificial layer, and performing isotropic etching which stops on the liner oxide layer and removes the first non-conformal sacrificial layer except from a remaining portion of the first non-conformal sacrificial layer disposed on the corner sides of the channel hole.

The method further comprises preferentially depositing a second sacrificial layer on the surface of the liner oxide layer except on the remaining portion of the first sacrificial layer which is disposed on the corner sides of the channel hole. Following the deposition of the second sacrificial layer, the remaining portion of the first sacrificial layer which is disposed on the corner sides of the channel hole is removed by etching to form open areas not protected by the first or the second sacrificial layers.

The remaining portion of the first sacrificial layer may be separated by a dry or wet separation process.

The method further comprises separating at the open areas an exposed portion of the liner oxide layer to expose in turn a portion of the channel poly-Si layer, then separating the exposed portion of the poly-Si layer to expose in turn a portion of the second oxide layer, then separating the exposed portion of the second oxide layer to expose in turn a portion of the nitride layer, then separating the exposed portion of the nitride layer to expose in turn a portion of the first oxide layer to form a pair of continuous multi-slit cells.

The method provides multi-slit cells which are formed at the opposite wider, less curved sides of the oval shape channel hole. The multi-slit cells are covered by a remaining portion of the sacrificial layer.

The method further comprises removing the remaining portion of the second sacrificial layer and gap-filling an open space of the channel hole with an oxide to complete the forming of the MSCs.

In yet another embodiment, a method for making MSCs comprises providing a stack of alternating thin films of oxides and nitrides, forming a channel hole having a pillar shape extending through the stack, forming a first oxide layer, a nitride layer, and a second oxide layer sequentially over a sidewall of the channel hole, forming a channel poly-Si layer on the second oxide layer, covering the channel poly-Si layer with a liner oxide layer, and forming a reverse non-conformal reverse sacrificial layer on the liner oxide layer. The method further comprises performing an oxidation operation to form a growth oxide layer, wherein the growth oxide layer is formed with a thickness differentiated by curvature induced stress. The non-conformal sacrificial layer may be a poly-Si layer that is non-conformally deposited and partially oxidized to form the growth oxide layer.

The method may further comprise cutting the growth oxide layer at the corners of the channel hole, and once the oxide layer is cut at the corners of the channel hole, then cell cutting is performed to form cell areas on opposite wide sides of the channel hole. An opened space of the channel hole separating the cell areas may be gap-filled with a gap-fill oxide, tier nitride layers may be removed and word lines may be formed to replace the nitride layers via a metallization operation. These and other features and advantages of the present invention will become apparent to those skilled in the art of the invention from the following detailed description in conjunction with the following drawings.

### BRIEF DESCRIPTION OF THE FIGURES

FIGS. 1A to 12A, 1B to 12B, and 1C to 12C illustrate a method of making a discrete-type dual slit cell with sacrificial channel cut according to an embodiment of the present invention. FIGS. 1A to 12A are plan views of an oval shape channel structure, FIGS. 1B to 12B are cross-sectional views taken along line A-A′ of the corresponding FIGS. 1A to 12A, and FIGS. 1C to 12C are cross-sectional views taken along line B-B′ of the corresponding FIGS. 1A to 12A.

FIGS. 13A to 24A, 13B to 24B, and 13C to 24C illustrate a variation of the inventive method. FIGS. 13A to 24A are plan views of an oval shape channel structure, FIGS. 13B to 24B are cross-sectional views taken along line A-A′ of the corresponding FIGS. 13A to 24A, and FIGS. 13C to 24C are cross-sectional views taken along line B-B′ of the corresponding FIGS. 13A to 24A.

FIGS. 25A to 40A, 25B to 40B, and 25C to 40C illustrate another variation of the inventive method. FIGS. 25A to 40A are plan views of an oval shape channel structure, FIGS. 25B to 40B are cross-sectional views taken along line A-A′ of the corresponding FIGS. 25A to 40A, and FIGS. 25C to 40C are cross-sectional views taken along line B-B′ of the corresponding FIGS. 25A to 40A.

### DETAILED DESCRIPTION OF THE INVENTION

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present invention as defined in the appended claims.

The present invention is described herein with reference to cross-section and/or plan illustrations of idealized embodiments of the present invention. However, embodiments of the present invention should not be construed as limiting the inventive concept. Although a few embodiments of the present invention will be shown and described, it will be appreciated by those of ordinary skill in the art that changes may be made in these embodiments without departing from the principles and spirit of the present invention.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

It will be further understood that when an element is referred to as being “connected to”, or “coupled to” another element, it may be directly on, connected to, or coupled to the other element, or one or more intervening elements may be present. Furthermore, the connection/coupling may not be limited to a physical connection but may also include a non-physical connection, e.g., a wireless connection.

In addition, it will also be understood that when an element is referred to as being “between” two elements, it may be the only element between the two elements, or one or more intervening elements may also be present.

When a first element is referred to as being “over” a second element, it not only refers to a case where the first element is formed directly on the second element but also a case where a third element exists between the first element and the second element. When a first element is referred to as being “on” a second element, it refers to a case where the first element is formed directly on the second layer or the substrate.

It should be understood that the drawings are simplified schematic illustrations of the described devices and may not include well known details for avoiding obscuring the features of the invention.

It should also be noted that features present in one embodiment may be used with one or more features of another embodiment without departing from the scope of the invention.

It is further noted, that in the various drawings, like reference numbers designate like elements.

As used herein, singular forms are intended to include the plural forms as well, unless the context clearly indicates otherwise.

According to an aspect of the present invention, a method is provided of making an MSC structure comprising a uniform e-field multi-site-cell (uf-MSC) formation having less curvature for cell width. The method employs reverse sacrificial layer deposition or area-selective deposition. The method may provide uniform carrier injection for a 3D NAND device.

The present inventive method provides a continuous MSC (Multi-Site-Cell) structure that can secure sufficient channel area which has cell cutting while having enough storage nodes by reverse non-conformal sacrificial layer to separate (split) the main cell, and is a very effective method structurally compared to previous patents which have large curvature cell.

This present inventive method can drastically improve cell characteristics compared to the previous one due to less curvature multi-site cell which has a continuous and sufficient storage node area while cutting the cell layers by reverse non-conformal sacrificial layer after the channel poly-si and liner oxide deposition. Such uniform field multi-site-cells (uf-MSC) is formed by using less curvature for cell width split from elliptical main cell.

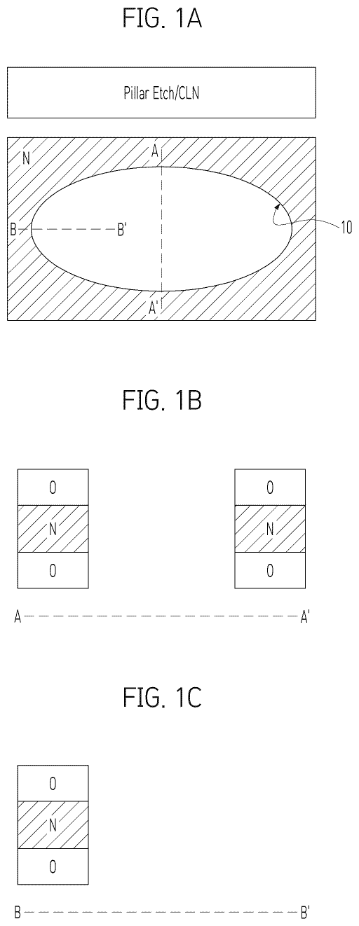

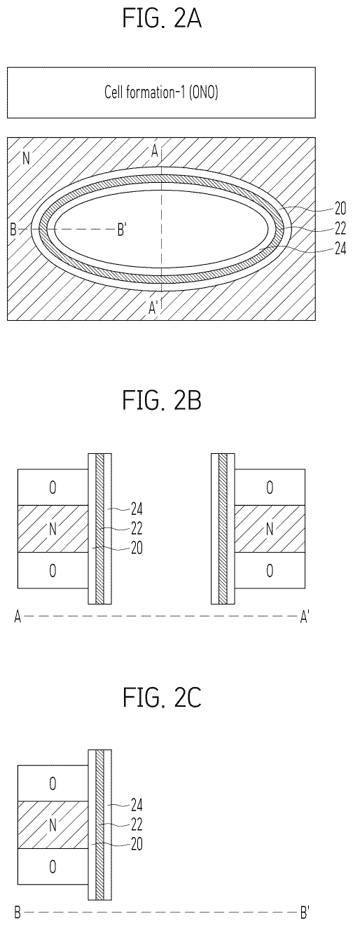

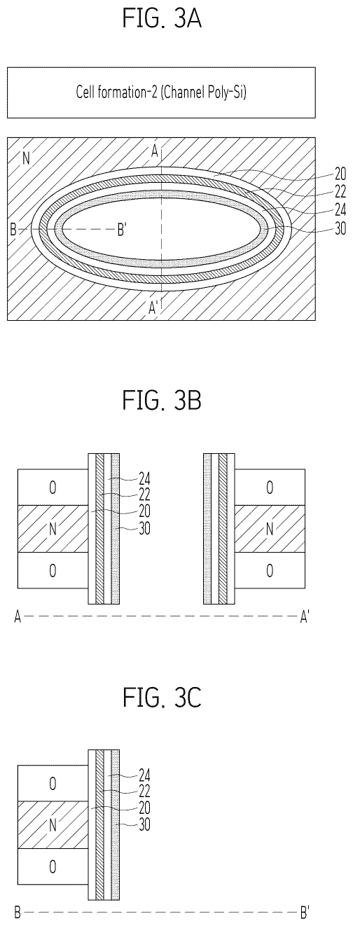

Referring now to FIGS. 1A to 1C, according to an embodiment, a layered structure of alternating thin films of oxides (“O”) and nitrides (“N”) is provided, referred to hereinafter as an ONON stack. A channel hole 10 is formed via etching and cleaning (also referred to as pillar ETCH/CLN) having a pillar shape extending through the ONON stack along a first axis perpendicular to the ONON stack. More specifically, after the pillar etch to form the vertical channel hole a cleaning operation ensures that any remaining particles from the etching are removed to form the channel hole 10. Then, referring to FIGS. 2A to 2C, a first oxide layer 20, a nitride layer 22, and a second oxide layer 24 may be formed sequentially over the sidewall of the channel hole 10. The first oxide layer 20, also referred to as a blocking oxide layer, is deposited on the sidewall of the channel hole 10 for electrical insulation from the word line (“WL”) layers which may be formed later according to the described method. Then, the nitride layer 22 is deposited on the first oxide layer 20 to cover the first oxide layer. The nitride layer 22 may be used to form the storage node for the MSC structure. Afterward, the second oxide layer 24, also referred to as the tunnel oxide layer, is formed on the nitride layer 22 to cover the nitride layer 22. The second oxide layer 24 may be formed, for example, by the same ONO deposition tool at one time, and then as shown in FIGS. 3A to 3C a channel poly-Si layer 30 is formed on the second oxide layer 24. The deposition of the channel poly-Si 30 may be performed using any suitable existing method such as, for example, chemical vapor deposition (LPCVD) or atomic layer deposition (ALD).

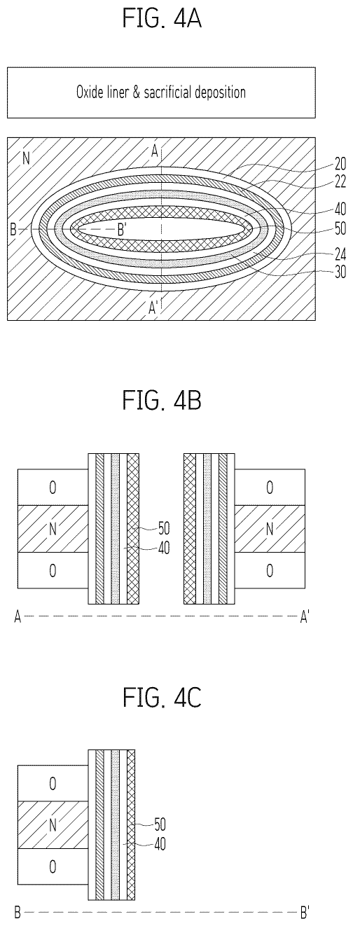

Referring to FIGS. 4A to 4C, the channel poly-Si layer 30, according to the present invention method for cutting the cell to form the multiple cells is covered by a thin third oxide layer 40, also referred to as a liner oxide layer to block poly-Si damage during the cell-cutting process. Following the formation of the liner oxide layer 40, to proceed with the cell-cutting process for forming a continuous MSC (Multi-site-cell), the method further includes direct deposition of a reverse non-conformal sacrificial layer 50 on the liner oxide layer 40. The reverse non-conformal layer 50 is thicker on the opposite sides along the short axis of the oval shape channel hole 10 and thinner on the opposite sides along the long axis of the oval shape channel hole 10. Reverse non-conformal sacrificial layer, dielectric or conductor, in the channel hole may be obtained with low to medium pressure chemical vapor deposition tool. By tuning the pressure, temperature, reactant gas ratio to alter the concentration gradient and diffusion in the channel hole confined space, anisotropic deposition rate can be achieved.

The opposite sides along the short axis of the oval shape channel hole 10 are also referred to as the wide sides of the channel hole 10. The opposite sides along the long axis of the oval shape channel hole 10 are also referred to as the narrow sides or corners of the channel hole 10.

The reverse non-conformal sacrificial layer 50 may use single or multi-layers using SiO₂, Si₃N₄, Poly-Si, metal, and metal silicide, and may be configured by additional oxidation and nitridation characteristics differences. For example, in some embodiments, there may be multiple sacrificial layer stacking inside the cell after NAND cell formation. Because the NAND cell layers 22, 24 and 30 are to be separated into 2, or more, sub-cells, the separation etch process starts from the outermost sacrificial layer with good etch selectivity to an underneath sacrificial layer. For this season more than two materials of different properties in dielectric-to-dielectric, dielectric-to-poly-Si (or metal), and metal-to metal multi-layer may be deployed. In addition, because of different oxidation rate or nitridation rate of such material system, the thus formed oxide or nitride can present different thickness and etch rate which is beneficial for the cell separation etch processing.

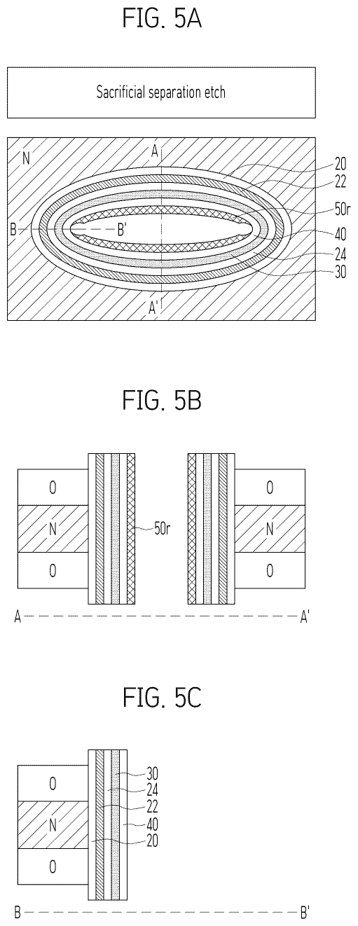

Specifically, afterward, the reverse non-conformal sacrificial layer 50 is separated at a thinner area instead of a thicker area thereof as illustrated in FIGS. 5A to 5C. For example, the non-conformal sacrificial layer may be separated by a dry or wet separation process. The remaining sacrificial layer on the wide sides of the channel hole is denoted with numeral 50r.

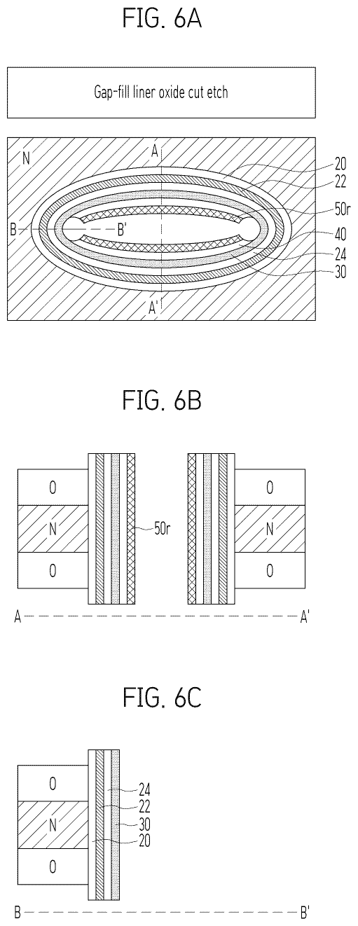

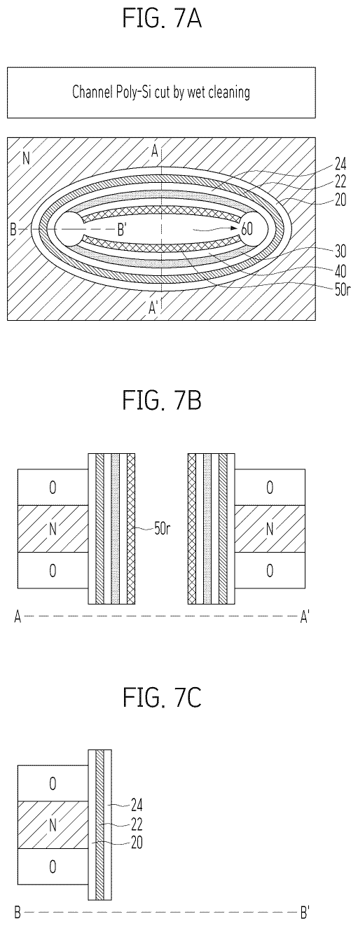

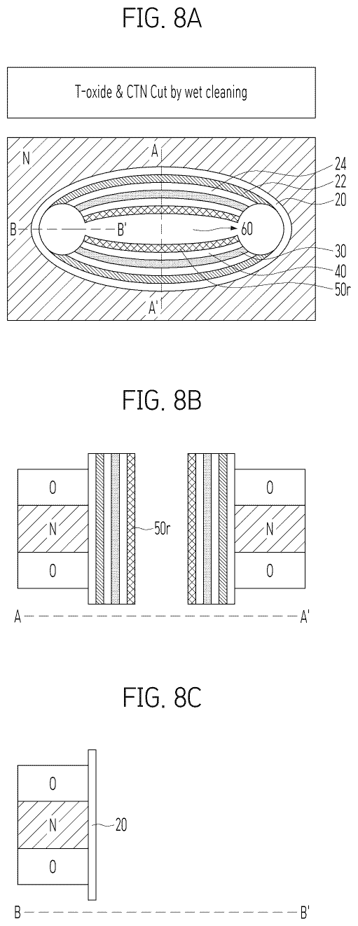

Referring to FIGS. 6A to 8C, the method further includes separating the exposed thin liner oxide layer 40 (as shown in FIGS. 6A to 6C), the channel poly-Si 30 (as shown in FIGS. 7A to 7C), the tunnel oxide layer 24, and the charge trap nitride layer 22 (as shown in FIGS. 8A to 8C) of the opened areas 60 to form continuous multi-slit cells. The separating of the thin liner oxide layer, the channel poly-Si, the tunnel oxide layer, and the charge trap nitride layer of the opened areas 60 may include a dry or wet etching operation for separating the thin liner oxide layer, the channel poly-Si, the tunnel oxide layer, and the charge trap nitride layer of the opened areas to form the continuous multi-slit cells on the opposite wide sides of the channel hole.

At this time, the cell layers at both sides (the wide less curved sides) of the oval shape channel hole which are covered by the sacrificial layer 50r remain substantially intact during the dry or wet etching.

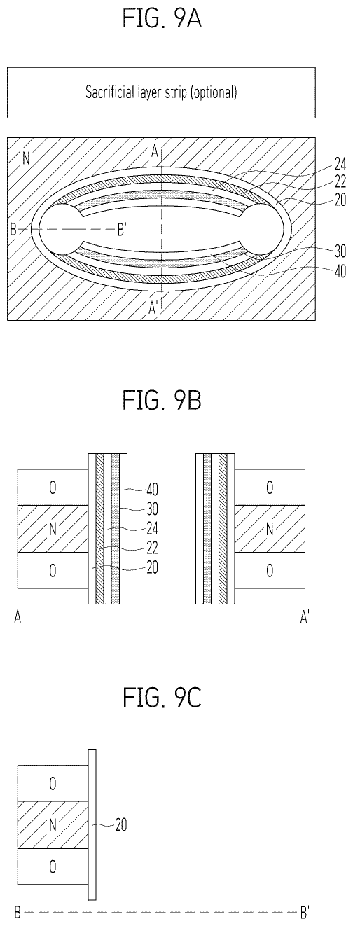

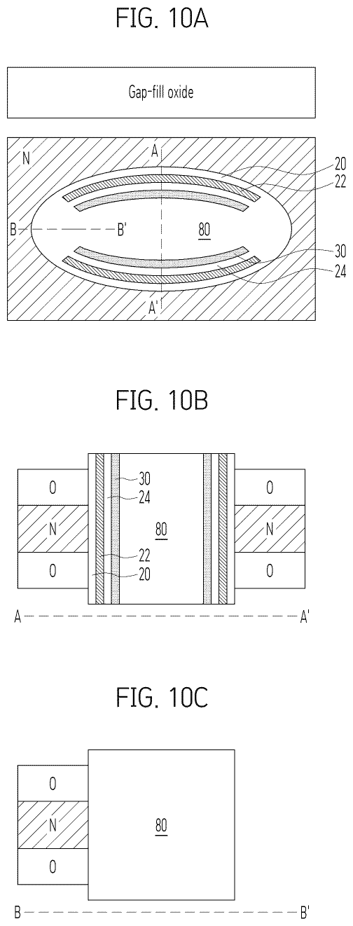

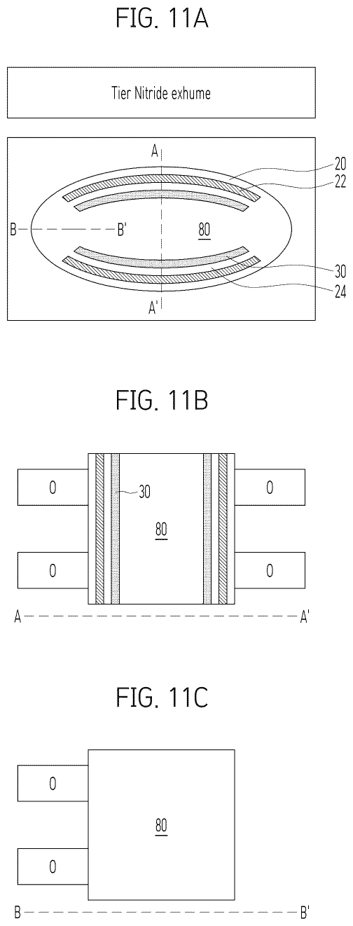

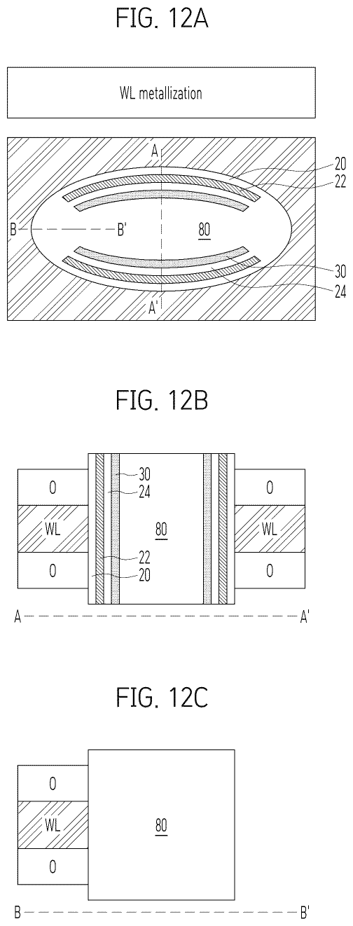

The next operations include removing the remaining sacrificial layer 50r through a dry or wet cleaning process as shown in FIGS. 9A to 9C, gap-filling the open space with an oxide 80 as shown in FIGS. 10A to 10C, exhuming the tier nitride layers as shown in FIGS. 11A to 11C, and forming word lines WL by performing metallization of the previous tier nitride layers as shown in FIGS. 12A to 12C. The removing of the remaining sacrificial layer 50r may be optional. Through this process flow, two MSCs are formed which have enough channel area and less curvature.

### Separation by Area Selective Deposition

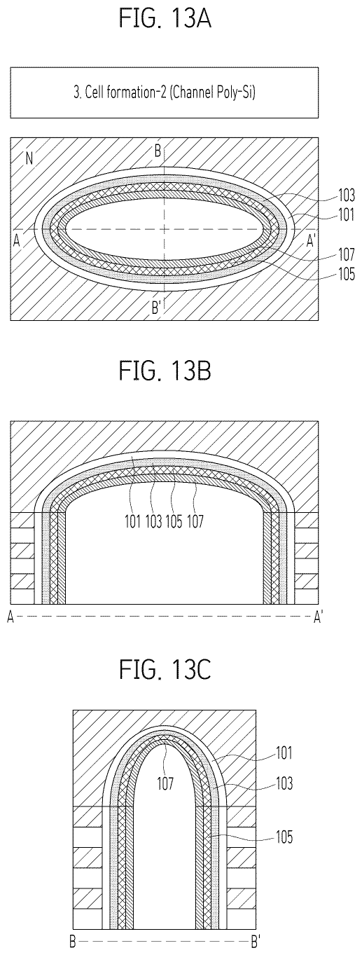

A variation of the inventive method is illustrated in FIGS. 13A to 24C The method includes a modified cell separation technique which includes area-selective deposition (ASD) of a second sacrificial layer after a liner oxide layer and a first non-conformal sacrificial layer deposition and isotropic etch which stops on the liner oxide layer. The liner may be an oxide layer or a nitride layer, or a combination of both.

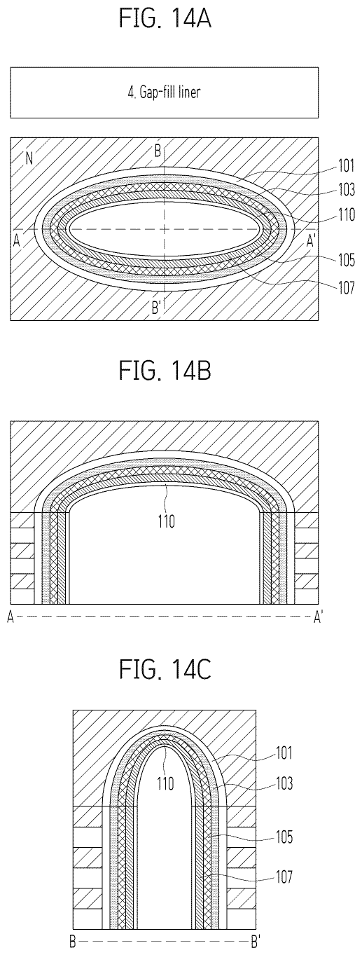

Specifically, referring to FIGS. 13A to 13C an oval shaped channel hole 10 is shown extending in an ONON stack of alternating tier oxide “O” and nitride “N” layers. The channel hole 10 is covered by a stack of layers including a first oxide layer 101, a nitride layer 103 (also referred to as charge trap nitride layer), a second oxide layer 105 (also referred to as a tunnel oxide layer, and a channel poly-Si layer 107 formed sequentially over the sidewall of the channel hole 10 in the recited order. Referring to FIGS. 14A to 14C a gap-fill liner 110 (also referred to as a liner oxide layer 110) is formed on the Poly-Si layer 107. The gap-fill liner 110 may be a thin liner oxide layer formed, for example, by low pressure (LP) chemical vapor deposition (CVD) or atomic layer deposition (ALD). The gap-fill liner 110 may also be referred to as a thin liner oxide layer.

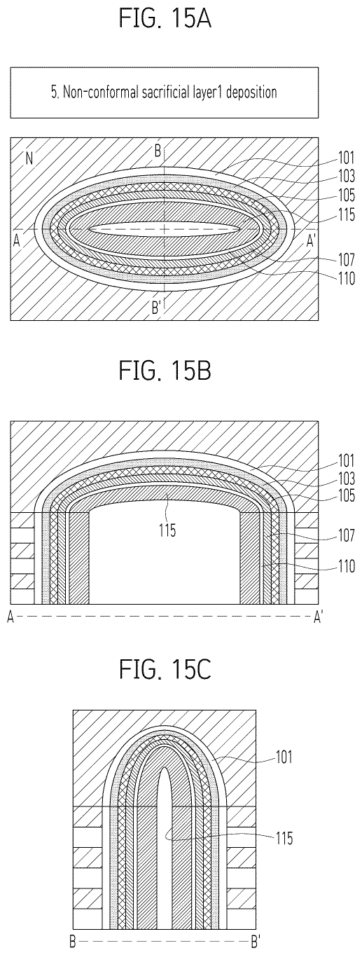

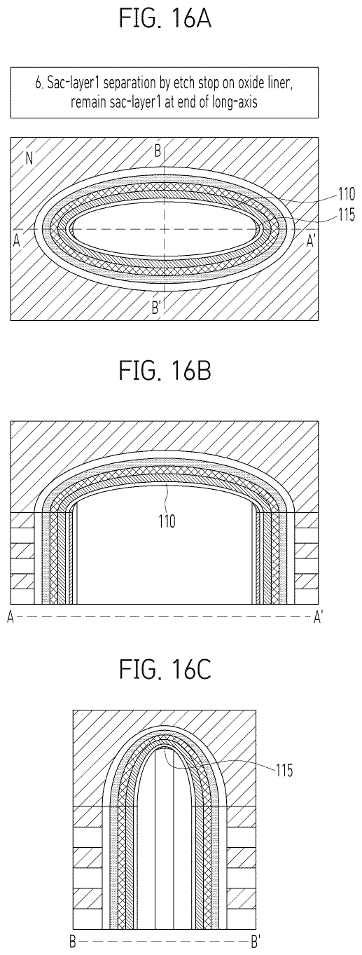

Referring now to FIGS. 15A to 15C, the method may further include deposition of a first non-conformal sacrificial layer 115. The method may further include separation of the first sacrificial layer 115. For example, by isotropic etching which stops on the gap-fill liner 110 and leaves a remaining first sacrificial layer 115 only on the corners of the oval shape channel hole as illustrated in FIGS. 16A to 16C. The isotropic etch operation removes the first non-conformal sacrificial layer except from the corners of the channel hole also referred to as the ends of the long axis of the oval shape channel hole.

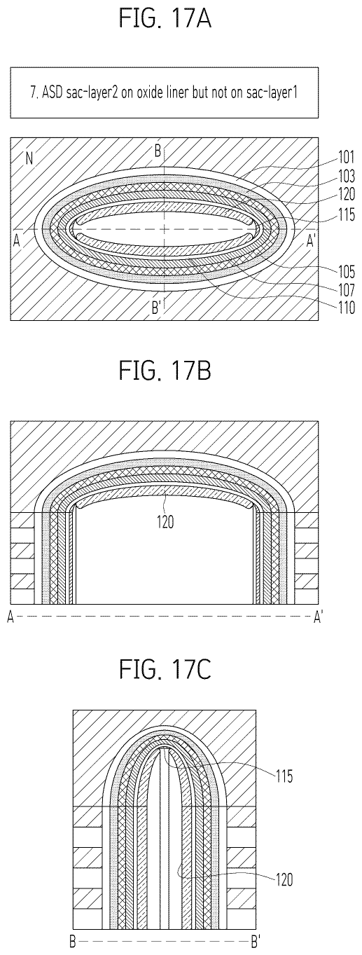

Then, as shown in FIGS. 17A to 17C, a second sacrificial layer 120 is preferentially deposited on the surface of the liner oxide layer 110. Importantly, the second sacrificial layer 120 is not deposited on the surface of the first sacrificial layer 115 which is disposed on the corners of the channel hole along the long-axis of the oval shape channel hole.

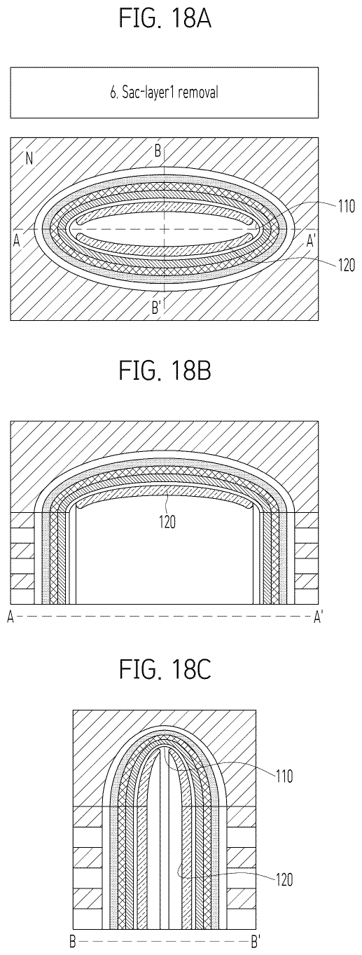

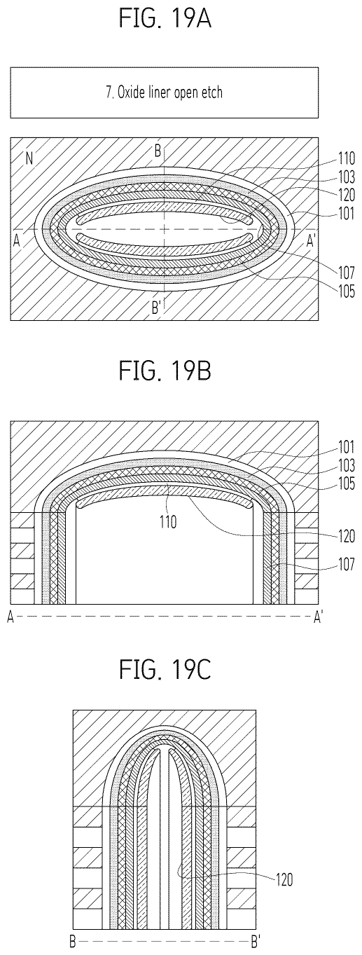

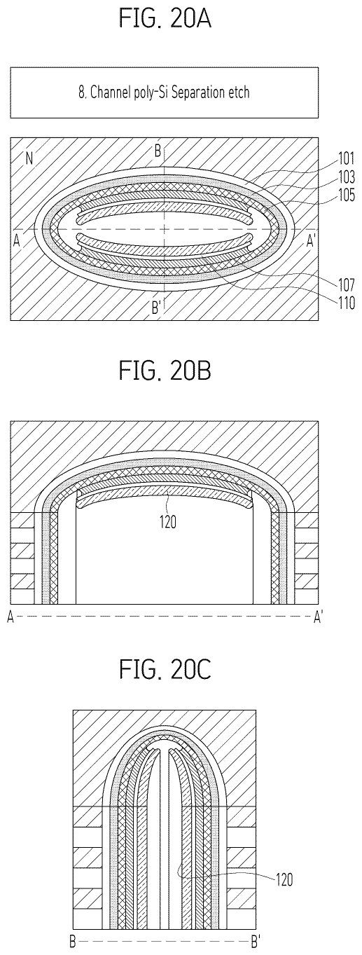

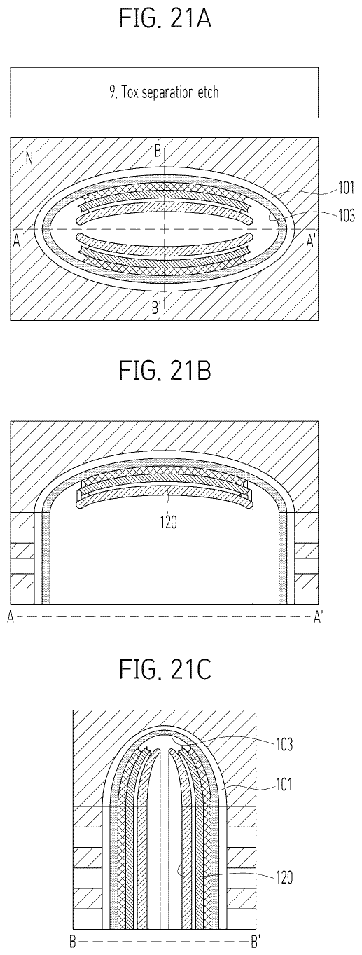

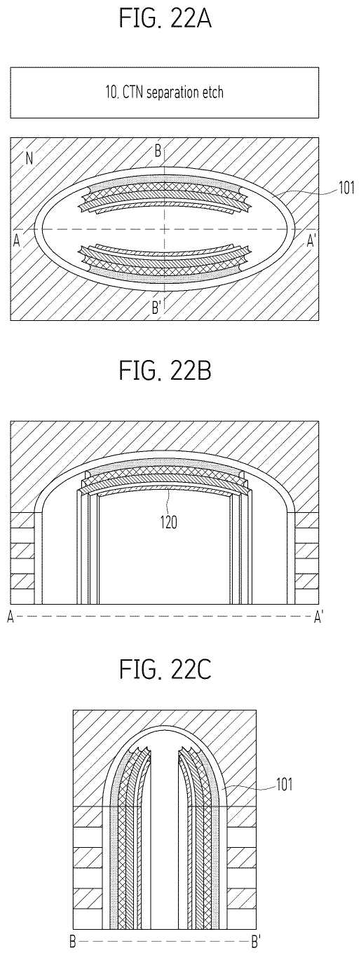

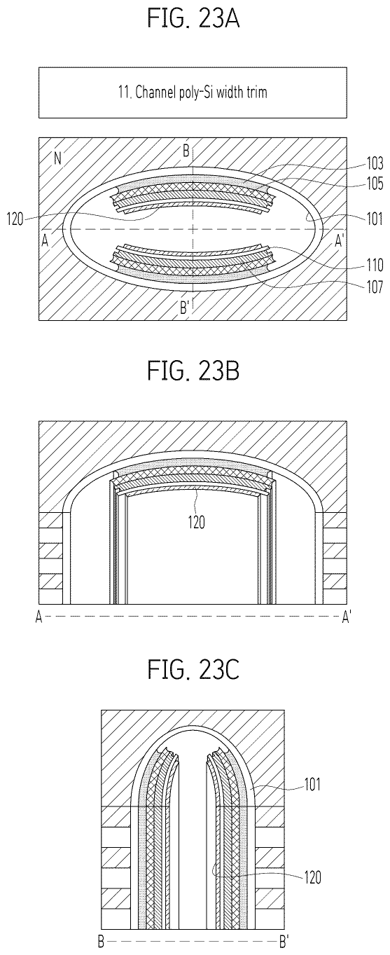

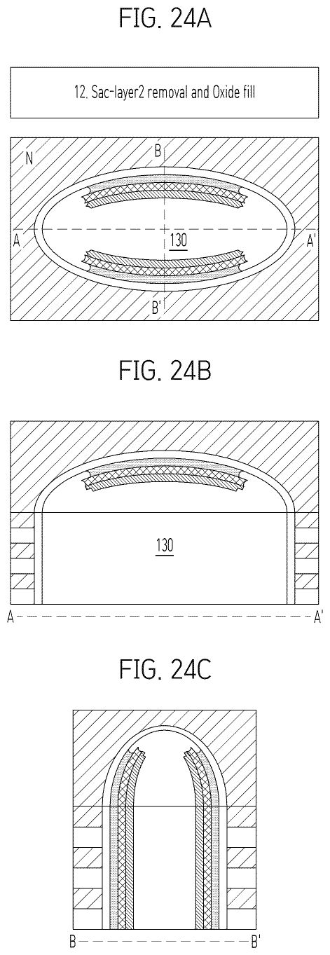

The method may further include operations of removing the remaining first sacrificial layer 115 from the corners of the channel hole as shown in FIGS. 18A to 18C, separating the exposed liner oxide layer 110 as shown in FIGS. 19A to 19C, separating the exposed channel poly-Si layer 107 as illustrated in FIGS. 20A to 20C, separating the tunnel oxide layer 105 as illustrated in FIGS. 21A to 21C, and the charge trap nitride layer 103 of the opened corner areas as illustrated in FIGS. 22A to 22C to form continuous multi-site cells. The above separating operations of the liner oxide layer 110, the channel poly-Si 107, the tunnel oxide layer 105, and the charge trap nitride 103 of the opened areas may be made through a dry or wet etching process. At this time, the cell layers at both sides covered by the second sacrificial layer remain substantially intact during dry or wet etching. The method may further include an operation of trimming the width of the poly-Si layer as shown in FIGS. 23A to 23C. Channel width trimming is performed by an isotropic etch to remove portion of channel material sandwiched between the other two layers. The objective is to adjust the channel width to optimize cell electrical performance. Following the trimming of the poly-Si layer the method further comprises removing the second sacrificial layer 120 and filling with an oxide 130 the opened area as illustrated in FIGS. 24A to 24C.

### Non-Conformal Sacrificial Layer Deposition Followed by Curvature Dependent Oxidation

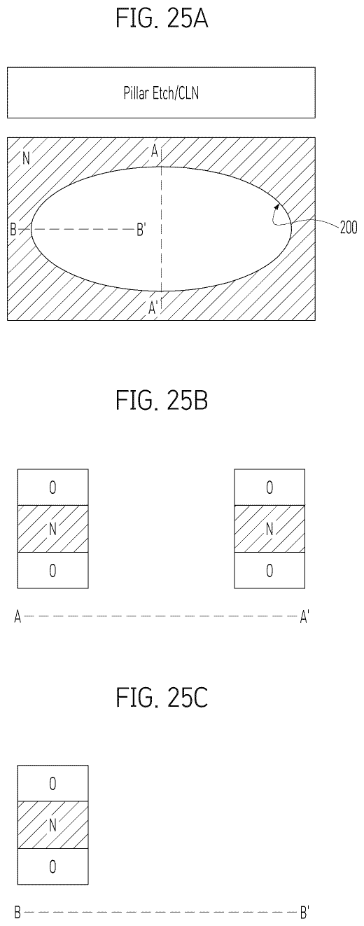

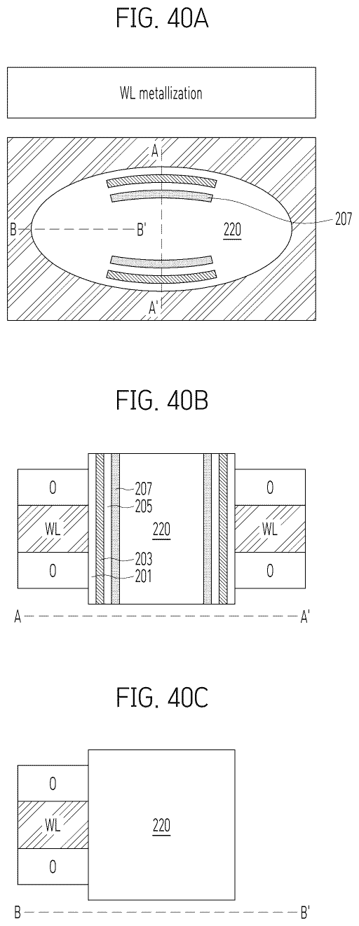

Referring now to FIGS. 25A to 40C, another variation of the inventive method is provided which comprises a non-conformal sacrificial layer deposition followed by curvature dependent oxidation.

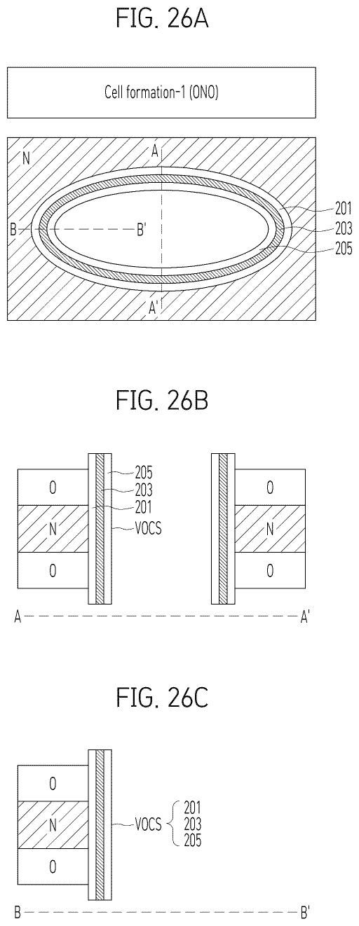

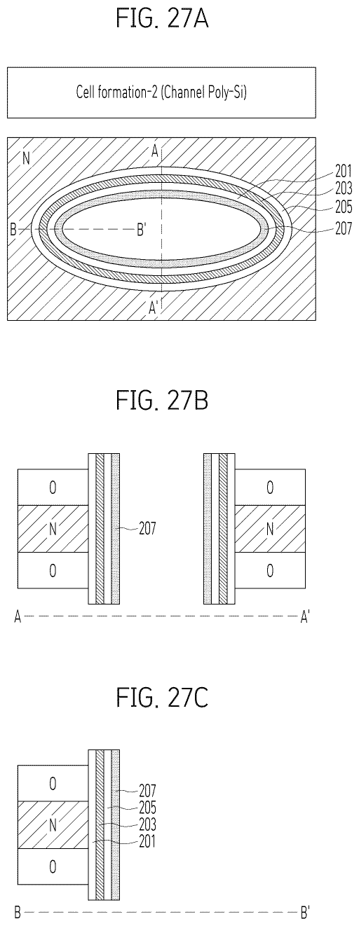

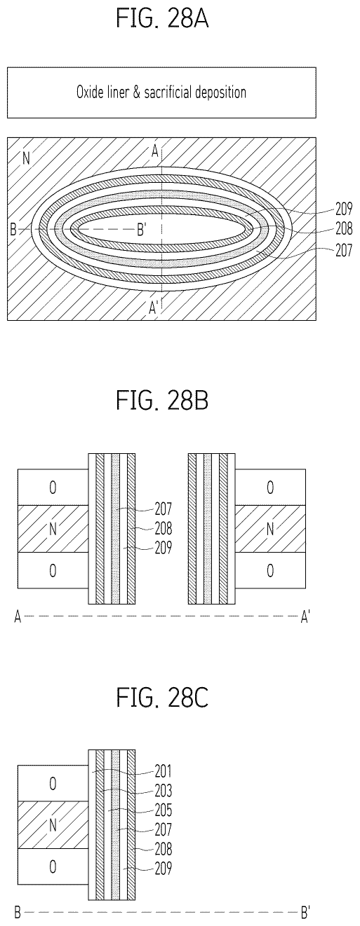

More specifically, as illustrated in FIGS. 25A to 25C, an oval shaped channel hole 200 is formed in an ONON stack of alternating oxide “O” and nitride “N” layers. The method may then include an operation of forming a vertical ONO stack covering the sidewall of the channel hole 200 as illustrated in FIGS. 26A to 26C. The vertical ONO stack is generally denoted with VOCS (vertical ONO cover stack) and may include a first oxide layer 201 (also referred to as a blocking oxide layer), a nitride layer 203 (also known as a charge trap nitride layer), and a second oxide layer 205 (also known as a tunnel oxide layer). The method further includes forming a channel poly-Si layer 207 as illustrated in FIGS. 27A to 27C and then sequentially forming an oxide liner 209 and a nitride liner 208 over the channel poly-Si layer 207 as illustrated in FIGS. 28A to 28C.

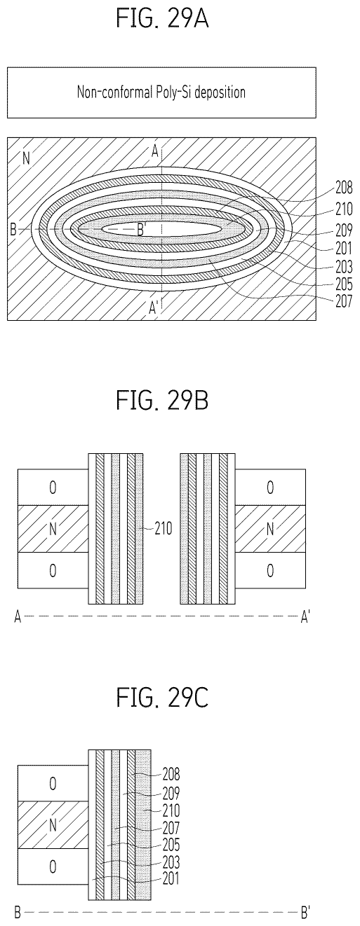

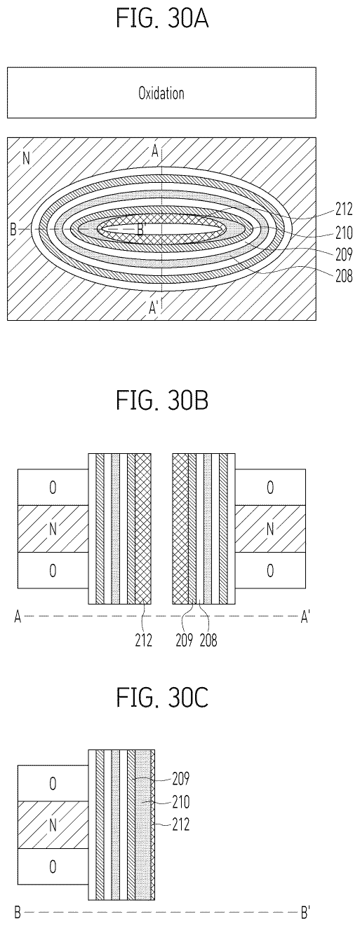

The method further comprises a non-conformal deposition of another poly-Si layer 210 deposition as shown in FIGS. 29A to 29C. The non-conformal poly-Si layer 210 has a larger thickness at the corners of the channel hole than in the wide sides of the channel hole. An oxidation operation is then performed and the growth oxide thickness is differentiated by curvature induced stress as illustrated in FIGS. 30A to 30C. At the corners of the channel hole thin oxidation is obtained because of the severe concave area which results in a self-limited oxidation reaction. At the wide sides of the channel hole oxidation is not limited and a growth oxide layer 212 is formed in an entire depth of the additional poly-Si layer 210.

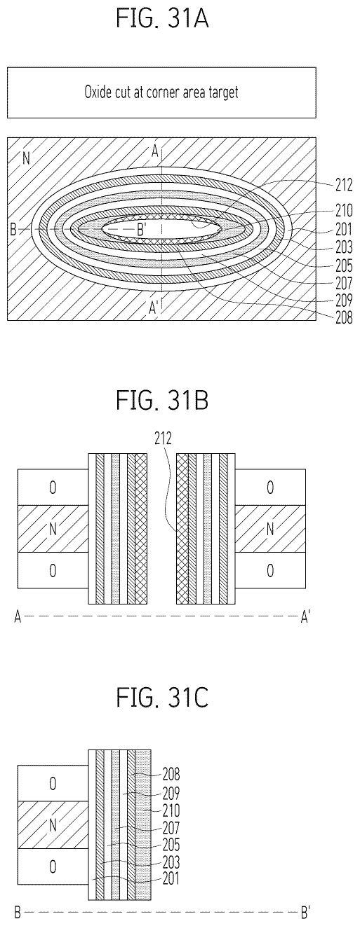

Then, as shown in FIGS. 31A to 31C, the growth oxide layer 212 is cut at the corners of the channel hole, e.g., by wet or dry etching. Once the growth oxide layer 212 is cut at the corners of the channel hole, then cell cutting by wet etching can be performed to form cell areas on the opposite wide sides of the channel hole.

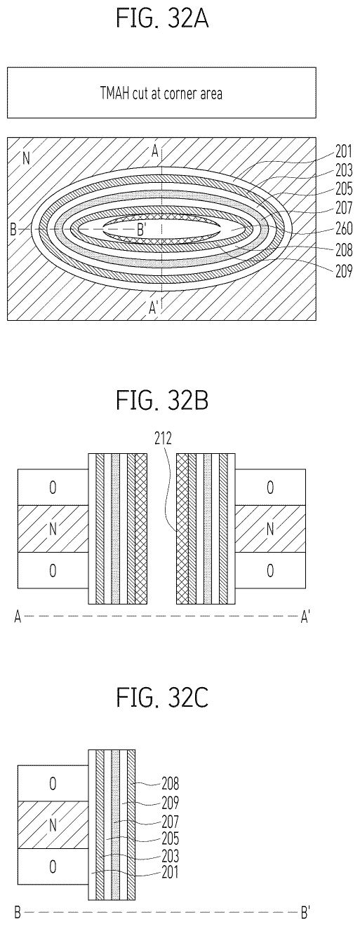

More specifically, as illustrated in FIGS. 32A to 32C, a TMAH cut at the corner areas may be performed first to cut the remaining poly-Si layer 210 from the corners of the channel hole and form an open area 260.

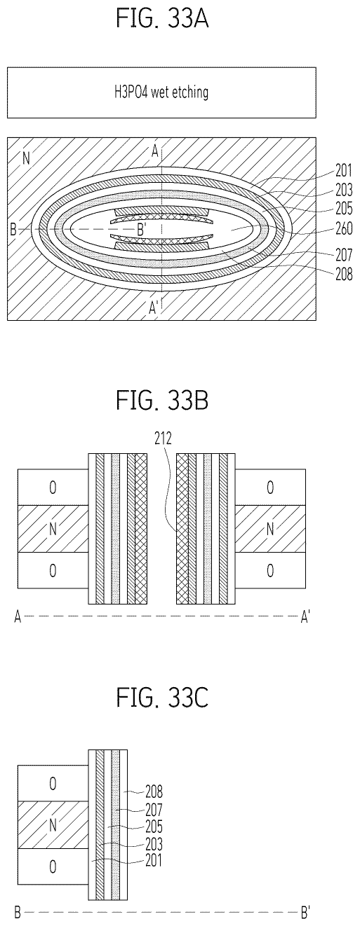

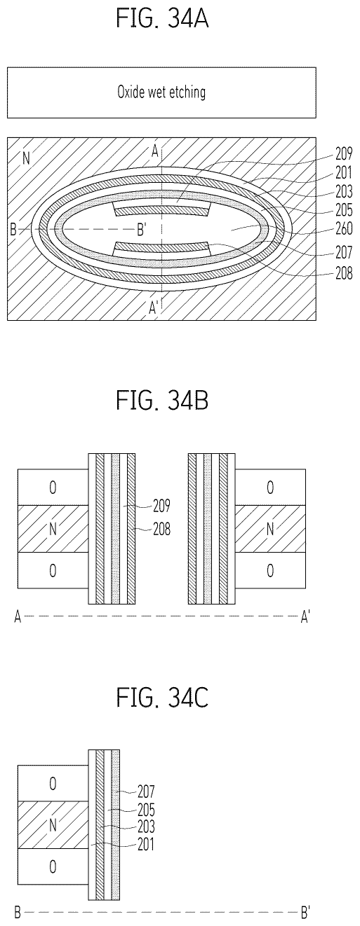

Then, as illustrated in FIGS. 33A to 34C, a first H₃PO₄ etching (FIGS. 33A TO 33c) followed by an oxide wet etching (FIGS. 34A to 34C) may be performed sequentially to cut the nitride and oxide liners from the corners of the channel hole and grow larger the open area 260.

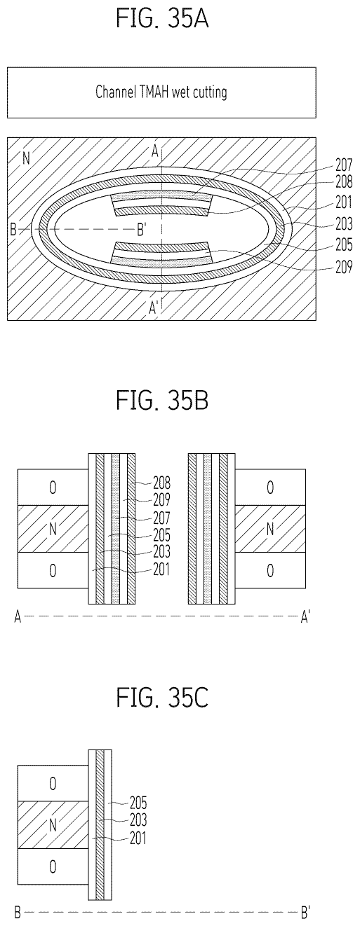

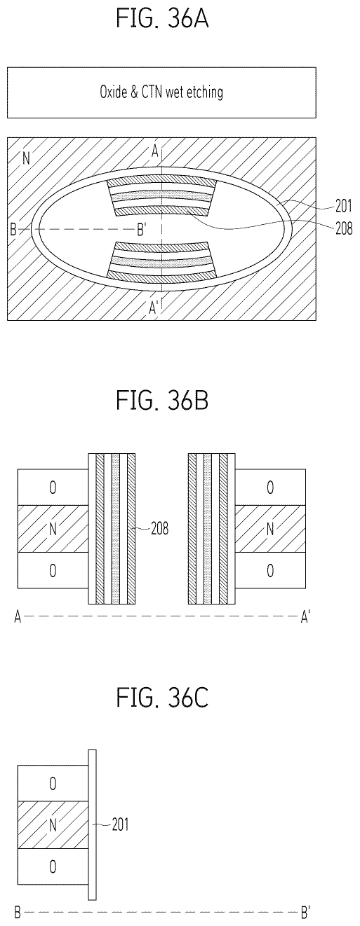

Then, as illustrated in FIGS. 35A to 35C, a channel TMAH wet cutting is performed followed by oxide and charge trap nitride wet etching illustrated in FIGS. 36A to 36C to expose the first oxide layer 201.

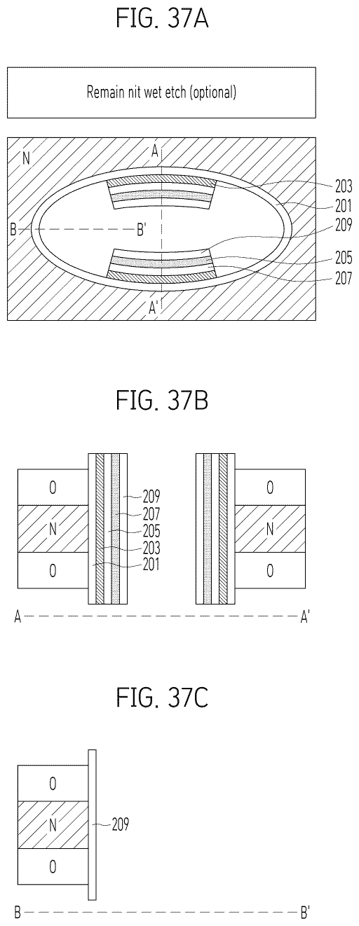

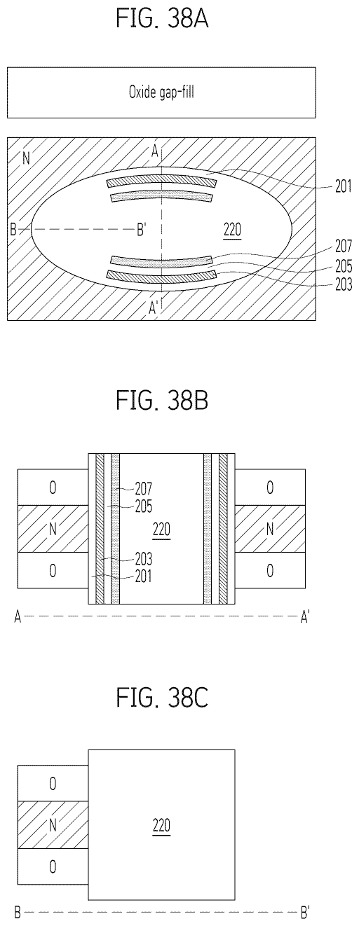

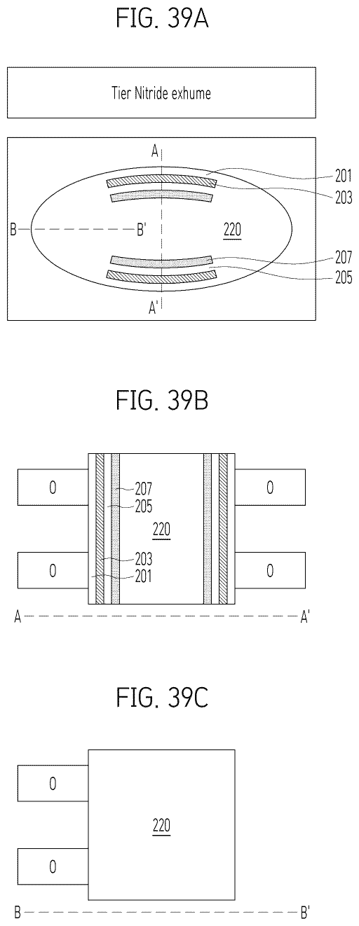

The method may further include an optional wet etch operation to remove a remaining nitride liner 208 as shown in FIGS. 37A to 37C, followed by an oxide gap-fill operation depositing an oxide 220 in the created open space inside the channel hole which separates the formed cell areas illustrated in FIGS. 38A to 38C. The method further includes a tier nitride exhume operation as illustrated in FIGS. 39A TO 39C removing the tier nitride layers followed by a metallization operation to form word lines WL in the previously tier nitride layers.

The present invention provides a method of forming multi-site cells by cutting the storage layer using non-conformal sacrificial layers which have reverse deposition characteristics in oval, triangular, and other polygonal shapes. The conventional cell structure physically forms one cell per layer on one pillar, but when the storage layer is separated as in this patent, each cell can act as an individual cell. Therefore, the present invention can dramatically overcome the limitations of vertical scaling in current 3D NAND. Also, the present invention method can secure sufficient storage nodes and less curved multi-site cells for lower non-uniform carrier injection compared to the previous channel-cutting scheme which have smaller and curved areas.

Although the invention has been described in reference to a dual slit cell embodiment, the present invention generally relates to a method of forming multi-slit cells. The conventional cell structure physically forms one cell per layer on one pillar, but according to the present invention method each separated section of a cell can function as an independent cell. Therefore, the present invention can dramatically overcome the limitations of vertical scaling in current 3D NAND semiconductor devices.

What is claimed is:

1. A method for making multi-slit cells comprising:
providing a stack of alternating thin films of oxides and nitrides;
forming an oval shape channel hole extending through the stack;
forming a first oxide layer, a nitride layer, and a second oxide layer sequentially over a sidewall of the oval shape channel hole;
forming a channel poly-Si layer on the second oxide layer;
covering the channel poly-Si layer with a liner oxide layer; and
forming a reverse non-conformal sacrificial layer on the liner oxide layer,
wherein a thickness of the reverse non-conformal sacrificial layer at a center of a wide side of the oval shape channel hole is thicker than a thickness of the reverse non-conformal sacrificial layer at a center of a narrow side of the oval shape channel hole.

2. The method of claim 1, wherein the oval shape channel hole has two wide sides opposite to each other and two narrow sides opposite to each other, and
wherein the wide sides are wider and less curved than the narrow sides.

3. The method of claim 1, wherein the reverse non-conformal sacrificial layer includes single or multi-layers of SiO₂, Si₃N₄, Poly-Si, metal, and metal silicide.

4. The method of claim 2, wherein the reverse non-conformal sacrificial layer is separated at the center of the narrow sides of the oval shape channel hole to form open areas exposing the liner oxide layer.

5. The method of claim 4, wherein the reverse non-conformal sacrificial layer is separated by a dry or wet separation process.

6. The method of claim 4, further comprising:
separating the exposed liner oxide layer to expose a portion of the channel poly-Si layer,
separating the exposed portion of the poly-Si layer to expose in turn a portion of the second oxide layer,
separating the exposed portion of the second oxide layer to expose in turn a portion of the nitride layer, and
separating the exposed portion of the nitride layer to expose in turn a portion of the first oxide layer to form a pair of continuous multi-slit cells.

7. The method of claim 6, wherein the separating of the exposed portions of the thin liner oxide layer, the channel poly-Si, the second oxide layer, and the nitride layer of the opened areas include a dry or wet etching operation to form continuous multi-slit cells.

8. The method of claim 6, wherein the multi-slit cells are formed at the opposite wide sides of the oval shape channel hole, and wherein the multi-slit cells are covered by a remaining portion of the sacrificial layer.

9. The method of claim 6, further comprising removing the remaining portion of the sacrificial layer and gap-filling an open space of the channel hole with an oxide to complete the forming of the multi-slit cells.

10. A method for making multi-slit cells comprising:
providing a stack of alternating thin films of oxides and nitrides;
forming an oval shape channel hole having a pair of opposite narrower corner sides alternating with a pair of opposite wider, less curved sides and extending through the stack;
forming a first oxide layer, a nitride layer, and a second oxide layer sequentially over a sidewall of the channel hole;
forming a channel poly-Si layer on the second oxide layer;
covering the channel poly-Si layer with a liner oxide layer;
depositing a first non-conformal sacrificial layer; and
performing isotropic etching which stops on the liner oxide layer and removes the first non-conformal sacrificial layer except from a remaining portion of the first non-conformal sacrificial layer disposed on the corner sides of the channel hole.

11. The method of claim 10, further comprising preferentially depositing a second sacrificial layer on the surface of the liner oxide layer except on the remaining portion of the first sacrificial layer which is disposed on the corner sides of the channel hole.

12. The method of claim 11, further comprising etching the remaining portion of the first sacrificial layer which is disposed on the corner sides of the channel hole to form open areas not protected by the first or the second sacrificial layers.

13. The method of claim 12, wherein the remaining portion of the first sacrificial layer is separated by a dry or wet separation process.

14. The method of claim 12, further comprising:
separating at the open areas an exposed portion of the liner oxide layer to expose in turn a portion of the channel poly-Si layer,
separating the exposed portion of the poly-Si layer to expose in turn a portion of the second oxide layer,
separating the exposed portion of the second oxide layer to expose in turn a portion of the nitride layer, and
separating the exposed portion of the nitride layer to expose in turn a portion of the first oxide layer to form a pair of continuous multi-slit cells.

15. The method of claim 14, wherein the multi-slit cells are formed at the opposite wider, less curved sides of the oval shape channel hole, and
wherein the multi-slit cells are covered by a remaining portion of the sacrificial layer.

16. The method of claim 15, further comprising removing the remaining portion of the second sacrificial layer and gap-filling an open space of the channel hole with an oxide to complete the forming of the multi-slit cells.

17. A method for making multi-slit cells comprising:
providing a stack of alternating thin films of oxides and nitrides;
forming a channel hole having a pillar shape extending through the stack;
forming a first oxide layer, a nitride layer, and a second oxide layer sequentially over a sidewall of the channel hole;
forming a channel poly-Si layer on the second oxide layer;
covering the channel poly-Si layer with a liner oxide layer and a liner nitride layer;
forming a reverse non-conformal sacrificial layer on the liner nitride layer; and
performing an oxidation operation on the reverse non-conformal sacrificial layer to form a growth oxide layer,
wherein the growth oxide layer is formed with a thickness differentiated by curvature induced stress.

18. The method of claim 17, wherein the reverse non-conformal sacrificial layer is a poly-Si layer that is non-conformally deposited and partially oxidized to form the growth oxide layer.

19. The method of claim 18, further comprising cutting the growth oxide layer at corners of the channel hole to expose a remaining portion of the reverse non-conformal layer at the corners of the channel hole, and performing cell cutting to form cell areas on opposite wide sides of the channel hole.

20. The method of claim 19, wherein an opened space of the channel hole separating the cell areas is gap-filled with a gap-fill oxide, and
wherein tier nitride layers are exhumed and a metallization operation is performed to form word lines.
